(19) United States
(12) Patent Application Publication
(10) Pub. No.: US 2021/0020238 A1
(43) Pub. Date: Jan. 21, 2021

(54) BINARY-TO-TERNARY CONVERTER USING A COMPLEMENTARY RESISTIVE SWITCH

(71) Applicant: NEC Corporation, Minato-ku, Tokyo (JP)

(72) Inventors: Xu BAI, Tokyo (JP); Toshitsugu SAKAMOTO, Tokyo (JP); Yukihide TSUJI, Tokyo (JP); Makoto MIYAMURA, Tokyo (JP); Ryusuke NEBASHI, Tokyo (JP); Ayuka TADA, Tokyo (JP)

(73) Assignee: NEC Corporation, Minato-ku, Tokyo (JP)

(21) Appl. No.: 16/980,211

(22) PCT Filed: Mar. 23, 2018
(86) PCT No.: PCT/JP2018/013518

§ 371 Date: Sep. 11, 2020

(51) Int. Cl. G11C 13/00; H03M 5/02; H03K 19/1776

(52) U.S. Cl. CPC G11C 13/004; G11C 13/0069; H03K 19/1776; G11C 13/0028; H03M 5/02; G11C 13/0026

(57) ABSTRACT

A reconfigurable circuit includes: a complementary resistive switch including a first resistive switch, a second resistive switch and a selection transistor, wherein a first terminal of the first resistive switch is connected to a first terminal of the second resistive switch and connected to a first terminal of the selection transistor; a first current source having a first terminal connected to a second terminal of the first resistive switch and a second terminal connected to a ground voltage line; a second current source having a first terminal connected to a second terminal of the second resistive switch and a second terminal connected to the ground voltage line; and a resistor having a first terminal connected to a second terminal of the selection transistor and a second terminal connected to a power voltage line.

This application is a National Stage Entry of PCT/JP2018/013518 filed on Mar. 23, 2018, the contents of all of which are incorporated herein by reference, in their entirety.

### TECHNICAL FIELD

The present invention relates to a reconfigurable circuit using non-volatile complementary resistive switches.

### BACKGROUND ART

A typical semiconductor integrated circuit (IC) is constructed by transistors built on a semiconductor substrate and upper layer wires used to connect the transistors. The patterns of transistors and wires are determined in a design stage of the IC. Interconnections between the transistors and wires cannot be changed after fabrication. In order to improve flexibility of IC, field-programmable gate arrays (FPGAs) have been proposed and developed. In FPGAs, configuration data including operation and interconnection information are stored in the memories, so that different logic operations and interconnections can be realized by configuring memories after fabrication according to requirements of end users. Interconnections within FPGA can be altered by switching between an ON state and an OFF state of switches in a routing multiplexer (MUX) or routing fabrics arranged in the FPGA in accordance with the interconnection information stored in the memories.

The relatively large energy consumption of FPGAs limits integration of commercial FPGAs into IoT (Internet of Things) devices. In most of commercial FPGAs, SRAM (Static Random Access Memory) is used to store the configuration data. Typically, each memory cell of SRAM is composed of six transistors and each modern FPGA chip has more than 10M (ten-million) memory cells of SRAM. This causes extremely large area overhead, cost, and energy consumption in FPGAs.

Recently, FPGAs with non-volatile resistive switches (NVRSs) such as Nanobridge® (NB) integrated between the wires upon a transistor layer have been proposed to overcome the problems of SRAM-based FPGAs and achieve small area overhead [NPL 1]. The NVRSs are used in routing blocks and LUT memories [PTL 1]. To achieve high off-state reliability, two NVRSs are serially connected to each other, face the opposite direction and are configured via the programming transistor, where the device is named as complementary NVRS (CNVRS) [NPL 2]. Moreover, redundant circuitry is introduced to relieve defective NVRSs automatically after shipment to improve its duration of use [PTL 2] [PTL 3].

### CITATION LIST

### Patent Literature

PTL 1: WO2015198573 A1
PTL 2: WO2016189751 A1
PTL 3: WO2017126451 A1

### Non Patent Literature

NPL 1: Xu Bai et al., A low-power Cu atom switch programmable logic fabricated in a 40 nm-node CMOS technology, Proc. IEEE Symp. VLSI Technol., 2017, pp. 28-29.
NPL 2: Munehiro Tada, et al., Improved OFF-State Reliability of Nonvolatile Resistive Switch with Low Programming Voltage, IEEE TRANSACTIONS ON ELECTRON DEVICES, Vol. 59, No. 9, pp. 2357-2362, SEPTEMBER 2012.
NPL 3: Makoto Miyamura, et al., 0.5-V highly power-efficient programmable logic using nonvolatile configuration switch in BEOL”, Proc. FPGA, 2015, pp. 236-239.

### SUMMARY OF INVENTION

### Technical Problem

The FPGA using CNVRS has better reliability than that using NVRSs, however, it requires twice as much read time to get the ON/OFF state of two NVRSs for each CNVRS, which greatly increases automotive repair time if defects occur.

Specifically, the reading time becomes large as follows.

FIG. 14 shows a structure of the FPGA 1c using a plurality of CNVRSs 101. The FPGA 1c is composed of a reconfigurable cell array 10, a controller 20, a write circuit 30, a read circuit 40 and a defect detection circuit 50. The write circuit 30 is used to apply a set voltage Vset or a reset voltage Vrst to each of NVRSs 1011 in the reconfigurable cell array 10 in order to implement different applications according to user's request. The controller 20 sends a row/column address and a NVRS selection signal (NVRSs 1011 S0 and S1 selection) to the write circuit 30 in order to determine to which a NVRS 1011 the signal Vset or Vrst should be applied. Each of the row/column addresses indicates a combination of one row and one column. The NVRS selection signal is to select one NVRS 1011 in a CNVRS 101 to be set/reset or read. The write circuit 30 determines the NVRS 1011 based on the row/column address and the NVRS selection signal. In the defect detection circuit 50, the actual ON/OFF state information of the CNVRSs 101 obtained by the read circuit 40 is compared with the original ON/OFF state information of the target application in order to find fail row/column addresses. The fail row/column addresses are the row/column addresses according to the defect. The controller 20 receives the fail row/column addresses from the defect detection circuit 50. The controller 20 determines which redundant row/columns in the reconfigurable cell array 10 should be used to relieve the FPGA 1b.

FIG. 15 shows a schematic view of the reconfigurable cell array 10 using the CNVRSs 101. Each cell 100 includes a routing multiplexer (MUX) 60 and a logic block 70. In this example, the logic block 70 includes two look-up tables (LUTs) 701, two D-type flip-flops 702 and two selectors 703. The routing MUX 60 includes a plurality of input and output lines 601 arranged in a lattice manner which are connected to the logic block 70 and adjacent cells 102. A data routing switch is arranged at each cross-point or intersection between the vertical lines and the horizontal lines. Therefore, the routing MUX 60 has a crossbar structure. Enlarged view shows four CNVRSs 101 which are arranged at cross-points between vertical lines LV0 and LV1 and horizontal lines LH0 and LH1. If the CNVRS 101 (S10 shown in FIG. 15) is in the ON-state, the vertical line LV0 is electrically connected to the horizontal line LH1. A signal can be transmitted from the input IN0 to the output OUT1. On the other hand, if the CNVRS 101 (S10) is in the OFF-state, the vertical line LV0 is not electrically connected to the horizontal line LH1. No signal can transmit from the input IN0 to the output OUT1.

FIG. 16A shows the structure of the CNVRS 101. As shown in FIG. 16A, the NVRS 1011 includes: active electrode T1 made of, for example, cupper (Cu); inert electrode T2 made of, for example, ruthenium (Ru); and solid-electrolyte IC sandwiched between active electrode T1 and inert electrode T2. FIG. 16B shows the symbolic of the NVRS 1011. If a positive set voltage (VSET) is applied between T1 and T2, resistance of the NVRS 1011 becomes low, called ON-state. On the other hand, if a negative reset voltage (VRST) is applied between T1 and T2, resistance of the NVRS 1011 becomes high, called OFF-state (FIG. 16C). The ratio of the high resistance and the low resistance is larger than 10⁵, so that the NVRS 1011 can be directly used as a switch for data routing [NPL 3]. FIG. 16D shows the CNVRS 101 which has three terminals TL, TM and TR. Two NVRSs 1011 are serially connected with opposite direction and are configured via the selection transistor 1012. The state of the CNVRS 101 is determined by both NVRSs 1011 (S0 and S1 shown in FIG. 16D). Only if both of them are in ON-state, the CNVRS 101 is at ON-state. Otherwise, the CNVRS 101 is at OFF-state (FIG. 16E).

A read cycle includes the following steps: 1. Apply a row/column address to the reconfigurable cell array 10. 2. Apply a NVRS selection signal to the reconfigurable cell array 10. 3. Active read control signal. 4. Obtain state of a NVRS 1011. 5. Drop the read control signal to terminate the read cycle. Therefore, it is necessary to use two read cycles to read two NVRSs 1011 (S0 and S1 shown in FIG. 16E) to get the state of one CNVRS 101, which causes large automotive repair time if defects occur.

This patent provides a multiple-valued circuit to improve automotive repair speed of the defect CNVRSs.

### Solution to Problem

According to an exemplary aspect of the present invention, there is provided a multiple-valued circuit comprising: a complementary resistive switch comprising a first resistive switch, a second resistive switch and a selection transistor, wherein a first terminal of the first resistive switch is connected to a first terminal of the second resistive switch and connected to a first terminal of the selection transistor, and a second terminal of the first resistive switch is a first terminal of the complementary resistive switch, a second terminal of the selection transistor is a second terminal of the complementary resistive switch, a second terminal of the second resistive switch is a third terminal of the complementary resistive switch; a first current source having a first terminal connected to the first terminal of the complementary resistive switch and a second terminal connected to a ground voltage line; a second current source having a first terminal connected to the third terminal of the complementary resistive switch and a second terminal connected to the ground voltage line; and a resistor having a first terminal connected to the second terminal of the complementary resistive switch and a second terminal connected to a power voltage line.

### Advantageous Effects of Invention

According to the multiple-valued circuit described above, the multiple-valued circuit can improve defect detection speed of the CNVRS.

### BRIEF DESCRIPTION OF DRAWINGS

FIG. 1 shows a structure of the FPGA using CNVRSs related to a first exemplary embodiment of the present invention.

FIG. 2 shows a binary-to-ternary converter circuit according to a first exemplary embodiment of the present invention.

FIG. 3 shows a multiple-valued read circuit according to a first exemplary embodiment of the present invention.

FIG. 4 shows a voltage level of the reference voltage in the multiple-valued read circuit according to a first exemplary embodiment of the present invention.

FIG. 5 shows a crossbar circuit using the multiple-valued read circuit according to a first exemplary embodiment of the present invention.

FIG. 6 shows a transistor-level sense amplifier according to a first exemplary embodiment of the present invention.

FIG. 7 shows a structure of the FPGA using CNVRSs related to a second exemplary embodiments of the present invention.

FIG. 8 shows a multiple-valued defect self-detection circuit according to a second exemplary embodiment of the present invention.

FIG. 9 shows voltage levels of the reference voltages in the multiple-valued defect self-detection circuit according to a second exemplary embodiment of the present invention.

FIG. 10 shows a crossbar circuit using the multiple-valued defect self-detection circuit according to a second exemplary embodiment of the present invention.

FIG. 11 shows a defect detection code according to a second exemplary embodiment of the present invention.

FIG. 12 shows a structure of the binary-to-ternary converter circuit in each exemplary embodiment.

FIG. 13 is a schematic block diagram showing a configuration of a computer according to at least one embodiment.

FIG. 14 shows a structure of the FPGA using CNVRSs related to exemplary embodiments of the present invention.

FIG. 15 shows a schematic view of the reconfigurable cell array using the CNVRSs related to exemplary embodiments of the present invention.

FIG. 16A is a first schematic showing the CNVRS related to exemplary embodiments of the present invention.

FIG. 16B is a second schematic showing the CNVRS related to exemplary embodiments of the present invention.

FIG. 16C is a third schematic showing the CNVRS related to exemplary embodiments of the present invention.

FIG. 16D is a fourth schematic showing the CNVRS related to exemplary embodiments of the present invention.

FIG. 16E is a fifth schematic showing the CNVRS related to exemplary embodiments of the present invention.

### DESCRIPTION OF EMBODIMENTS

Exemplary embodiment of the present invention will be next described with reference to the accompanying drawings.

### First Exemplary Embodiment

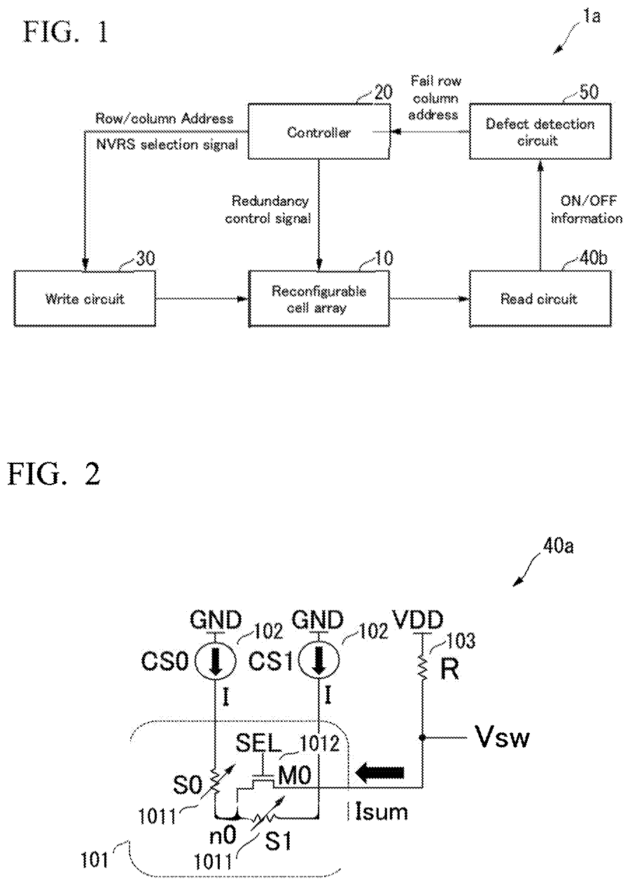

FIG. 1 shows a structure of the FPGA 1a according to a first exemplary embodiment of the present invention. The FPGA 1a includes a reconfigurable cell array 10, a controller 20, a write circuit 30, a multiple-valued read circuit 40b and a defect detection circuit 50.

FIG. 2 shows a binary-to-ternary converter circuit 40a according to a first exemplary embodiment of the present invention. The binary-to-ternary converter circuit 40a includes a CNVRS 101, two current sources 102 (CS0 and CS1 shown in FIG. 2), a resistor 103 (R shown in FIG. 2). The CNVRS 101 shown in FIG. 2 is the same as the CNVRS 101 shown in FIG. 12. The CNVRS 101 includes two NVRSs 1011 (S0 and S1 shown in FIG. 2) and a selection transistor 1012 (M0 shown in FIG. 2). Each of the NVRSs 1011 (S0 and S1) includes two terminals. The selection transistor 1012 (M0) includes three terminals named a gate terminal, a source terminal and a drain terminal. The gate terminal is controlled by a select signal SEL. The source terminal of the selection transistor 1012 (M0) is connected to a terminal of the NVRS 1011 (S0) and a terminal of the NVRS 1011 (S1). The CNVRS 101 includes terminals Ter1, Ter2, Ter3 and Ter4. The current source 102 (SC0) includes terminals Ter5 and Ter6. The current source 102 (SC1) includes terminals Ter7 and Ter8. The resistor 103 (R) includes terminals Ter9 and Ter10. The other terminal of the NVRS 1011 (S0) is connected to the terminal Ter1. The other terminal of the NVRS 1011 (S1) is connected to the terminal Ter2. The drain terminal is connected to the terminal Ter3. The gate terminal is connected to the terminal Ter4. The terminal Ter1 is connected to the terminal Ter5. The terminal Ter2 is connected to the terminal Ter7. The terminal Ter3 is connected to the terminal Ter9. The terminals Ter6 and Ter8 are connected to a ground voltage line (GND). The terminal Ter10 is connected to a power voltage line (VDD). A select signal SEL is applied to the terminal Ter4.

To speed up read operation of CNVRS 101, two NVRSs 1011 (S0 and S1 shown in FIG. 2) are read simultaneously. The NVRSs 1011 (S0 and S1) are connected to two current sources 102 (CS0 and CS1) having a current value is I [A], respectively, and then two current sources 102 (CS0 and CS1) are connected to the ground voltage line (GND). The ON-state resistance of the NVRS 1011 is about 1 k [ohms], and the OFF-state resistance of the NVRS 1011 is about 400 M [ohms] [NPL 3]. Therefore, if the NVRS 1011 (S0 or S1 shown in FIG. 2) is in an ON state, the current flowing through the NVRS 1011 (S0 or S1 shown in FIG. 2) is I [A]. On the other hand, if the NVRS 1011 (S0 or S1) is in an OFF state, there is almost no current flowing through the NVRS 1011 (S0 or S1 shown in FIG. 2). The current flowing through the NVRS 1011 (S0 shown in FIG. 2) and the current flowing through the NVRS 1011 (S1 shown in FIG. 2) are linearly summed at node n0 shown in FIG. 2, where the linearly summed current is named as Isum. When both the NVRSs 1011 (S0 and S1 shown in FIG. 2) are in an ON state, the current Isum is equal to 2 I [A]. When one of the NVRSs 1011 (S0 or S1 shown in FIG. 2) is in an ON state and the other of the NVRSs 1011 (S0 if one of the NVRSs 1011 is S1, S1 if one of the NVRSs 1011 is S0) is in an OFF state, the current Isum is equal to I [A]. When both the NVRSs 1011 (S0 and S1 shown in FIG. 2) are in an OFF state, the current Isum is nearly equal to 0 [A]. The source terminal of the selection transistor 1012 (M0 shown in FIG. 2) is the node n0 as shown in FIG. 2. The drain terminal is connected to the power voltage line (VDD) via the resistor 103 (R). The resistor 103 (R) is used to convert the ternary current signal Isum into a ternary voltage signal Vsw. When both the NVRSs 1011 (S0 and S1 shown in FIG. 2) are in an ON state, the voltage Vsw is equal to VDD-R×2 I [V]. When one of the NVRSs 1011 (S0 or S1 shown in FIG. 2) is in an ON state and the other of the NVRSs 1011 (S0 if one of the NVRSs 1011 is S1, S1 if one of the NVRSs 1011 is S0) is in an OFF state, the voltage Vsw is equal to VDD-R×I [V]. When the NVRSs 1011 (S0 and S1 shown in FIG. 2) are in an OFF-state, the voltage Vsw is nearly equal to VDD [V].

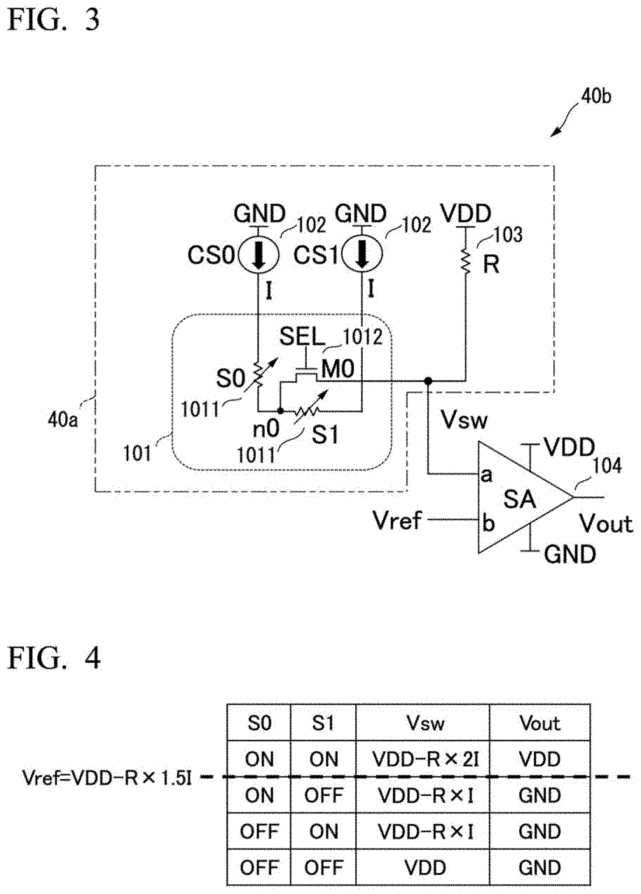

FIG. 3 shows a multiple-valued read circuit 40b. The multiple-valued read circuit 40b includes the binary-to-ternary converter circuit 40a and a sense amplifier 104 (SA shown in FIG. 3). The voltage Vsw output by the converter circuit 40a is applied to the first input terminal of the sense amplifier 104 (SA). A reference voltage (Vref) is applied to the second input terminal of the sense amplifier 104 (SA). The sense amplifier 104 (SA) compares with the voltage Vsw and the reference voltage (Vref). As shown in FIG. 4, when both the NVRSs 1011 (S0 and S1) are in an ON state, the CNVRS 101 is in an ON state and the voltage Vout is VDD [V]. Also, as shown in FIG. 4, when at least one of the NVRSs 1011 (S0 and S1) is in an OFF state, the CNVRS 101 is OFF state and the voltage Vout is 0 (GND) [V]. Therefore, when the voltage Vref is defined as VDD-R×1.5 I [V], the voltage Vout is VDD [V] in the case that both the NVRSs 1011 (S0 and S1) are in an ON state, and the voltage Vout is 0 (GND) [V] in case that at least one of the NVRSs 1011 (S0 and S1) is in an OFF state as shown in FIG. 4. In this case, the sense amplifier 104 (SA) implement AND function. The two NVRSs 1011 (S0 and S1) in a CNVRS is read at the same time. As a result, the ON/OFF state of the CNVRS 101 can be obtained in one read cycle.

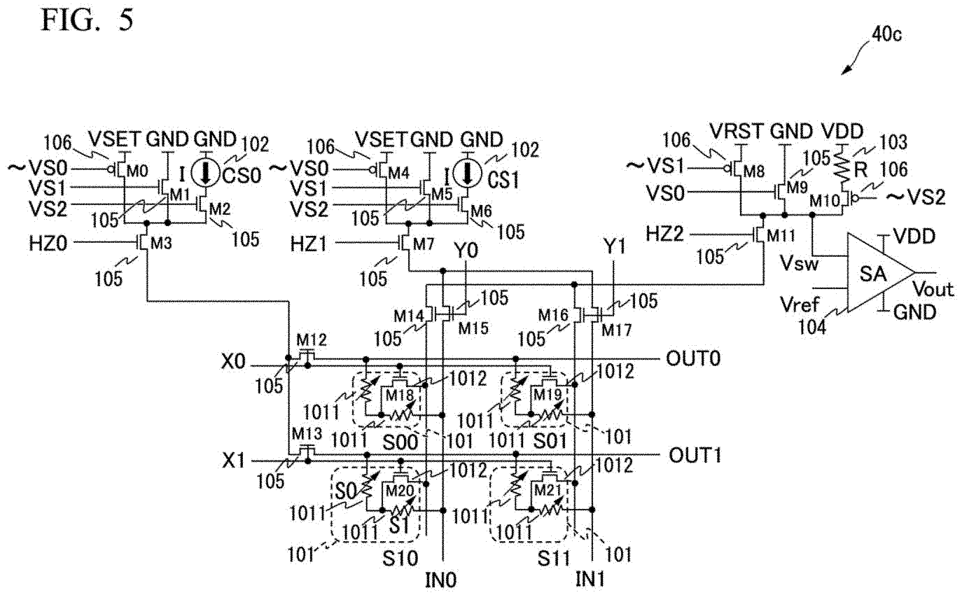

FIG. 5 shows a crossbar circuit 40c using the multiple-valued read circuit 40b. The read circuit 40c includes four CNVRSs 101 (S00, S01, S10 and S11), two current sources 102 (CS0 and CS 1), a resistor 103 (R), a sense amplifier 104 (SA), fourteen nMOS transistors 105 (M1, M2, M3, M5, M6, M7, M9, M11, M12, M13, M14, M15, M16 and M17), and four pMOS transistors 106 (M0, M4, M8 and M10).

Each of the CNVRSs 101 (S00, S01, S10 and S11) is the same as the CNVRS 101 shown in FIG. 12. The CNVRS 101 (S00) includes two NVRSs 1011 and a selection transistor 1012 (M18). The CNVRS 101 (S01) includes two NVRSs 1011 and a selection transistor 1012 (M19). The CNVRS 101 (S10) includes two NVRSs 1011 and a selection transistor 1012 (M20). The CNVRS 101 (S11) includes two NVRSs 1011 and a selection transistor 1012 (M21).

A 2×2 crossbar circuit is an example of the crossbar circuit 40c. Two input lines IN0 and IN1 shown in FIG. 5 are connected to two output lines OUT0 and OUT1 via four CNVRSs 101 (S00, S01, S10 and S11 shown in FIG. 5).

The CNVRS 101 (S00) includes terminals Ter11, Ter12, Ter13 and Ter14. The CNVRS 101 (S01) includes terminals Ter15, Ter16, Ter17 and Ter18. The CNVRS 101 (S10) includes terminals Ter19, Ter20, Ter21 and Ter22. The CNVRS 101 (S11) includes terminals Ter23, Ter24, Ter25 and Ter26. The pMOS transistor 106 (M0) includes three terminals Ter27, Ter28 and Ter29. The nMOS transistor 105 (M1) includes three terminals Ter30, Ter31 and Ter32. The nMOS transistor 105 (M2) includes three terminals Ter33, Ter34 and Ter35. The nMOS transistor 105 (M3) includes three terminals Ter36, Ter37 and Ter38. The pMOS transistor 106 (M4) includes three terminals Ter39, Ter40 and Ter41. The nMOS transistor 105 (M5) includes three terminals Ter42, Ter43 and Ter44. The nMOS transistor 105 (M6) includes three terminals Ter45, Te46 and Ter47. The nMOS transistor 105 (M7) includes three terminals Ter48, Ter49 and Ter50. The pMOS transistor 106 (M8) includes three terminals Ter51, Ter52 and Ter53. The nMOS transistor 105 (M9) includes three terminals Ter54, Ter55 and Ter56. The pMOS transistor 106 (M10) includes three terminals Ter57, Ter58 and Ter59. The nMOS transistor 105 (M11) includes three terminals Ter60, Ter61 and Ter62. The nMOS transistor 105 (M12) includes three terminals Ter63, Ter64 and Ter65. The nMOS transistor 105 (M13) includes three terminals Ter66, Ter67 and Ter68. The nMOS transistor 105 (M14) includes three terminals Ter69, Ter70 and Ter71. The nMOS transistor 105 (M15) includes three terminals Ter72, Ter73 and Ter74. The nMOS transistor 105 (M16) includes three terminals Ter75, Ter76 and Ter77. The nMOS transistor 105 (M18) includes three terminals Ter78, Ter79 and Ter80. The current source 102 (CS0) includes two terminals Ter 81 and Ter82. The current source 102 (CS1) includes two terminals Ter 83 and Ter84. The resistor 103 (R) includes two terminals Ter85 and Ter86. The sense amplifier 104 (SA) includes five terminals Ter87, Ter88, Ter89, Ter90 and Ter91.

The terminal Ter11 is connected to the terminals Ter15 and Ter63. The terminal Ter12 is connected to the terminals Ter20 and Ter72. The terminal Ter13 is connected to the terminals Ter21 and Ter69. The terminal Ter14 is connected to the terminals Ter18 and Ter65. The terminal Ter16 is connected to the terminals Ter24 and Ter78. The terminal Ter17 is connected to the terminals Ter25 and Ter75. The terminal Ter19 is connected to the terminals Ter23 and Ter66. The terminal Ter22 is connected to the terminals Ter26 and Ter68. The terminal Ter27 is connected to the terminals Ter30, Ter33 and Ter37. The terminal Ter34 is connected to the terminals Ter81. The terminal Ter36 is connected to the terminals Ter64 and Ter67. The terminal Ter39 is connected to the terminals Ter42, Ter45 and Ter49. The terminal Ter46 is connected to the terminals Ter83. The terminal Ter48 is connected to the terminals Ter73 and Ter79. The terminal Ter51 is connected to the terminals Ter54, Ter57, Ter61 and Ter87. The terminal Ter58 is connected to the terminals Ter85. The terminal Ter60 is connected to the terminals Ter70 and Ter76.

The terminals Ter11, Ter15 and Ter63 are connected to an output line OUT0. The terminals Ter19, Ter23 and Ter66 are connected to an output line OUT1. The terminals Ter12, Ter20 and Ter72 are connected to an input line IN0. The terminals Ter16, Ter24 and Ter78 are connected to an input line IN1. The terminals Ter28 and Ter40 are connected to a set voltage line VSET. The terminals Ter31, Ter43, Ter55, Ter82, Ter84 and Ter90 are connected to a ground voltage line GND. The terminal Ter52 is connected to a reset voltage line VRST. The terminals Ter86 and Ter91 are connected to a power voltage line VDD.

A reference voltage Vref is applied to the terminal Ter88. A row address signal X0 is applied to the terminals Ter14, Ter18 and Ter65. A row address signal X1 is applied to the terminals Ter22, Ter26 and Ter68. A column address signals Y0 is applied to the terminals Ter71 and Ter74. A column address signals Y1 is applied to the terminals Ter77 and Ter80. A voltage selection signal VS0 is applied to the terminals Ter56. A voltage selection signal VS1 is applied to the terminals Ter32 and Ter44. A voltage selection signal VS2 is applied to the terminals Ter35 and Ter47. A voltage selection signal ˜VS0 that is an inverse signal of the voltage selection signal VS0 is applied to the terminals Ter29 and Ter41. A voltage selection signal ˜VS1 that is an inverse signal of the voltage selection signal VS1 is applied to the terminal Ter53. A voltage selection signal ˜VS2 that is an inverse signal of the voltage selection signal VS2 is applied to the terminal Ter59. A High-Z selection signal HZ0 is applied to the terminal Ter38. A High-Z selection signal HZ1 is applied to the terminal Ter50. A High-Z selection signal HZ2 is applied to the terminal Ter62.

Thus, the nMOS transistors 105 (M12 to M21) for configuration of the crossbar circuit 40c are controlled by the row address signals X0 and X1 and the column address signals Y0 and Y1. The transistors 105 and 106 for set, reset and read operations (M0, M1, M2, M4, M5, M6, M8, M9 and M10) are controlled by the voltage selection signals VS0, VS1, VS2, ˜VS0, ˜VS1 and ˜VS2. The nMOS transistors 105 for set, reset, read and application operations (M3, M7 and M11) are controlled by the NVRS selection signals HZ0, HZ1 and HZ2.

Next, set, reset, read and application operations of the crossbar circuit 40c will be described. A set/reset cycle includes the following five steps. Step 1 is applying a row/column address to the reconfigurable cell array 10 shown in FIG. 1. Step 2 is applying NVRS selection signals HZ0, HZ1 and HZ2 to the reconfigurable cell array 10 shown in FIG. 1. Step 3 is activating set/reset control signal. Step 4 is setting/resetting a NVRS 1011 at the address location. Step 5 is dropping the set/reset control signal to terminate the set/reset cycle. It is necessary to set or reset one CNVRS 101 using two cycles. In case of setting the CNVRS 101 (S10) to be in an ON state, the signals VS0, X1, Y0 and HZ2 are set as HIGH, and the signals VS1, VS2, X0 and Y1 are set as LOW. At the first set cycle, the signals HZ0 and HZ1 are set as HIGH and LOW, respectively. A positive voltage VSET is applied to the selection transistor 1011 (S0), so that the resistance of the selection transistor 1011 (S0) becomes low. At the second set cycle, the signals HZ0 and HZ1 are set as LOW and HIGH, respectively. The positive voltage VSET is applied to the selection transistor 1011 (S1), so that the resistance of the selection transistor 1011 (S1) becomes LOW. In the case of resetting the CNVRS 101 (S10) to be in an OFF state, the signals VS1, X1, Y0 and HZ2 are set to be HIGH, and the signals VS0, VS2, X0 and Y1 are set to be LOW. At the first reset cycle, the signals HZ0 and HZ1 are set to be HIGH and LOW, respectively. A negative voltage −VRST is applied to the selection transistor 1011 (S0), so that the resistance of the selection transistor 1011 (S0) becomes HIGH. At the second reset cycle, the signals HZ0 and HZ1 are set as LOW and HIGH, respectively. A negative voltage −VRST is applied to the selection transistor 1011 (S1), so that a resistance of the selection transistor 1011 (S1) becomes HIGH. It is necessary to read each CNVRS 101 using only one cycle with the multiple-valued read circuit 40b. In case of reading the CNVRS 101 (S10), the signals VS2, X1, Y0, HZ0, HZ1 and HZ2 are set to be HIGH, and the signals VS0, VS1, X0 and Y1 are set to be LOW. When the currents generated by the two current sources 102 (CS0 and CS1) flow through M2, M3, M13 and M6, M7, M15 at the same time, respectively, a current flows through the CNVRS 101 (S10) via the transistors 105 and 106 (M20, M14, M11, M10). As described with reference to FIG. 3, the multiple-valued voltage signal Vsw is compared with Vref in the sense amplifier 104 (SA) to obtain an ON/OFF state of the CNVRS 101 (S10). In an application operation, all the control signals VS0 to VS2, HZ0 to HZ2, X0, X1, Y0 and Y1 are set to be LOW, and the input data signals are applied to the input lines IN0 and IN1 and transferred to output signals that are output to the output lines OUT0 and OUT1 according to the ON/OFF state of the four CNVRSs 101 (S00 to S11). As described above, a 2-to-2 routing MUX is implemented.

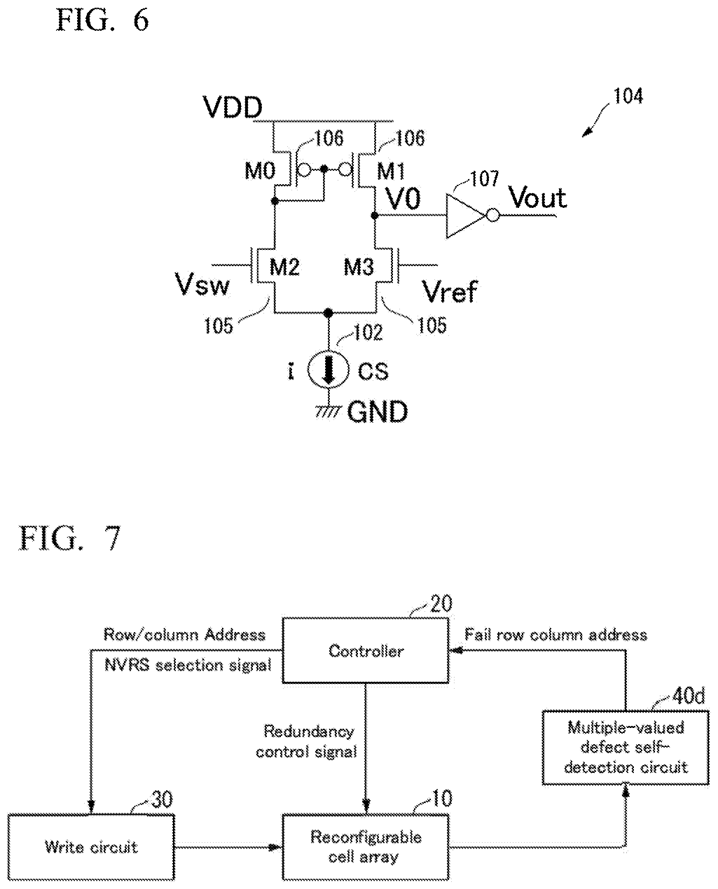

FIG. 6 shows a transistor-level structure of the sense amplifier 104 (SA). It includes two pMOS transistors 106 (M0 and M1), two nMOS transistors 105 (M2 and M3), a current source 102 (CS) and an inverter 107. The input signal Vsw is applied to the nMOS transistor 105 (M2). The reference voltage Vref is applied to the nMOS transistor 105 (M3). If the voltage Vsw [V] is higher than the voltage Vref [V], the current I [A] generated by the current source 102 (CS) flows through the pMOS transistor 106 (M0) and the nMOS transistor 105 (M2). As a result, an input voltage V0 of the inverter 107 becomes HIGH, and an output voltage Vout of the inverter 107 becomes LOW. On the other hand, if the voltage Vsw is lower than the voltage Vref, the current I generated by the current source 102 (CS) flows through the pMOS transistor 106 (M1) and the nMOS transistor 105 (M3). As a result, the input voltage V0 becomes LOW, and the output voltage Vout becomes HIGH.

### Second Exemplary Embodiment

Next, a second exemplary embodiment will be described.

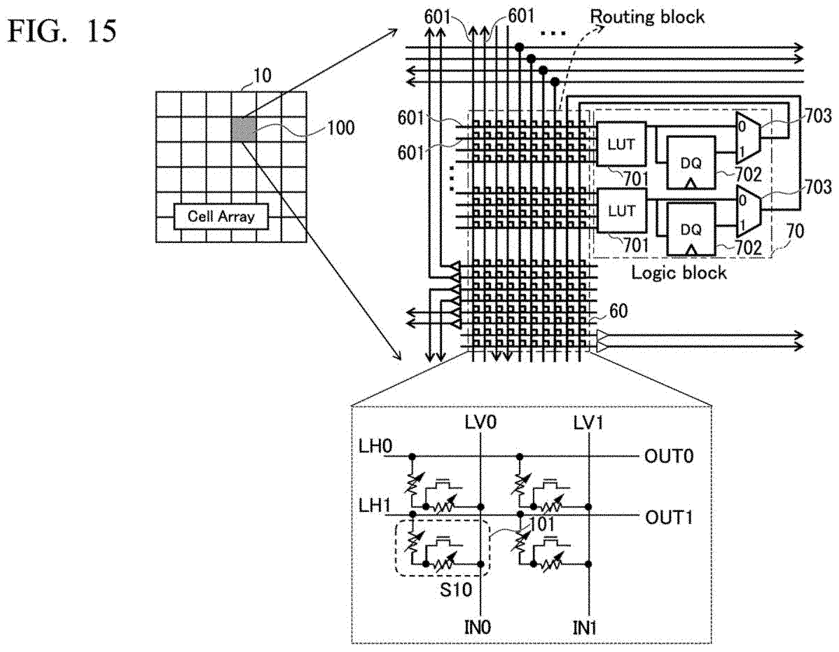

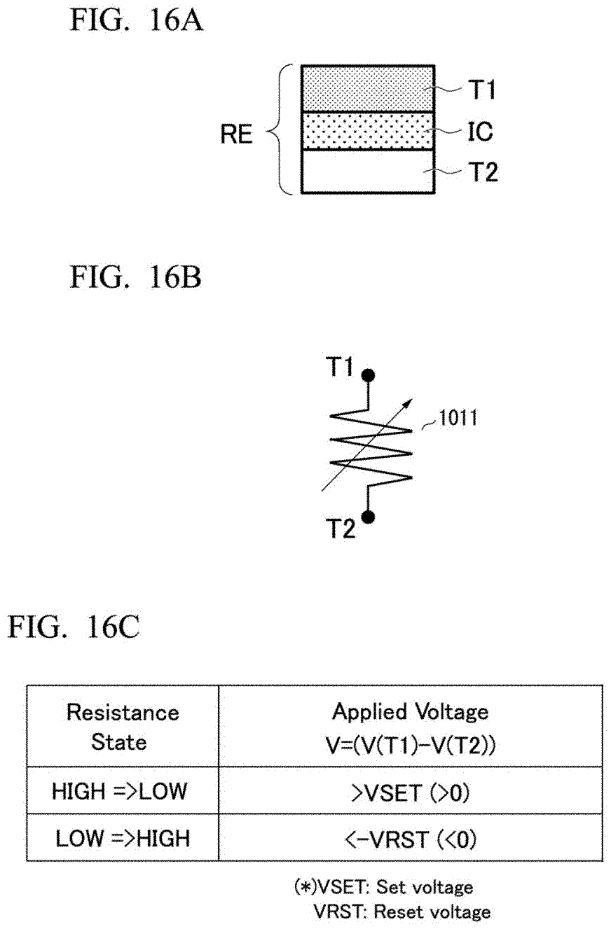

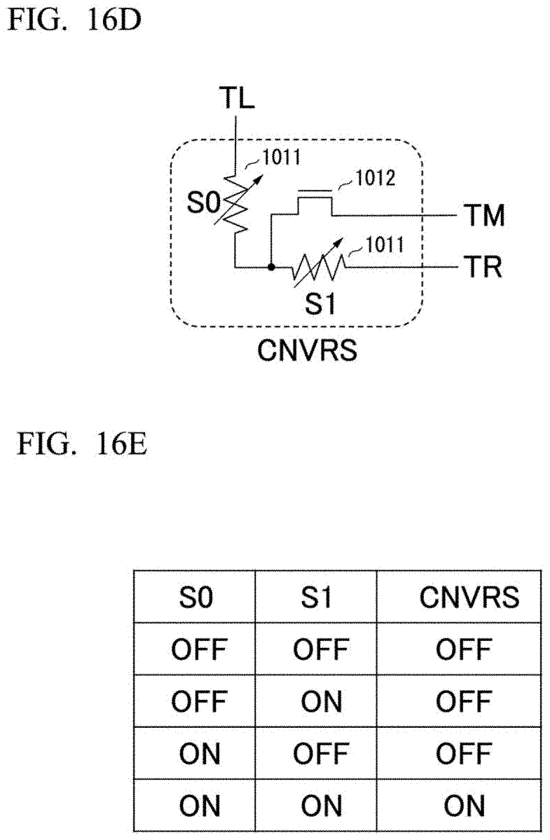

In the first exemplary embodiment, actual ON/OFF state information of the CNVRSs 101 obtained by the multiple-valued read circuit 40b is compared with the original ON/OFF state information of the target application in a defect detection circuit 50 in order to find fail row/column addresses. There is another kind of defect self-detection method [Patent Document 3] only comparing actual ON/OFF state of NVRSs 1011 (S0 and S1 shown in FIG. 15D) each other without comparing the actual ON/OFF state information with the original ON/OFF state information of the target application.

The defect self-detection principle is that no defect occurs in case that both the NVRSs 1011 (S0 and S1 shown in FIG. 15D) are in the same ON or OFF state, and defect occurs in case that the NVRSs 1011 (S0 and S1 shown in FIG. 15D) are in different states. Typically, it is necessary to read the states of the NVRSs 1011 (S0 and S1 shown in FIG. 15D) in two read cycles, and then perform an exclusive or function to detect defect. In the second exemplary embodiment, the binary-to-ternary converter circuit 40a is used to speed up the defect self-detection.

FIG. 7 shows a structure of the FPGA according to a second exemplary embodiment of the present invention. The FPGA includes a reconfigurable cell array 10, a controller 20, a write circuit 30 and a multiple-valued defect self-detection circuit 40d.

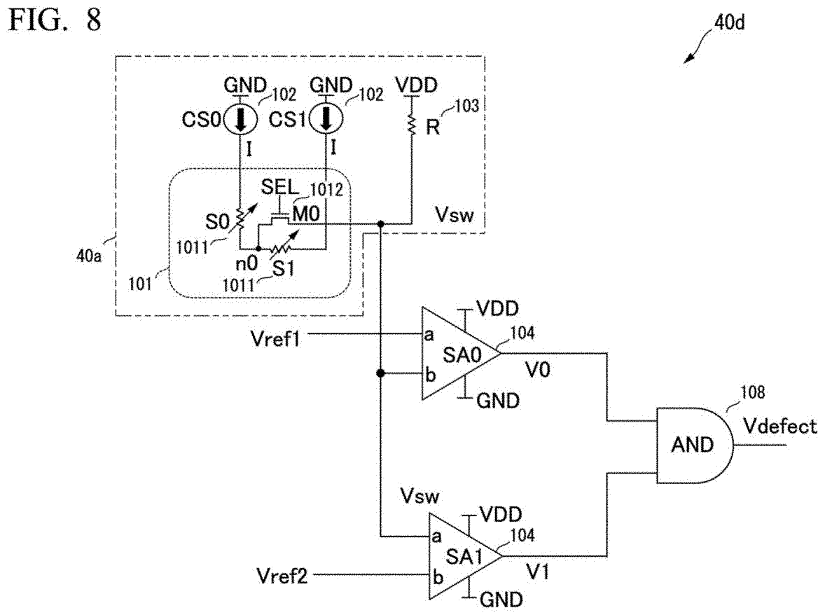

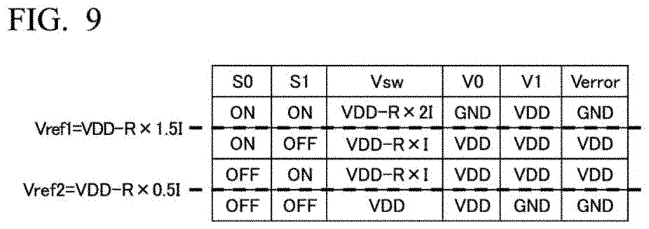

FIG. 8 shows a multiple-valued defect self-detection circuit 40d. The voltage Vsw is applied to two sense amplifiers 104 (SA0 and SA1) implementing NAND and OR functions of states of the NVRSs 1011 (S0 and S1), respectively. The multiple-valued defect self-detection circuit 40d includes binary-to-ternary converter circuit 40a, two sense amplifier 104 (SA0 and SA1), and an AND gate 108. The binary-to-ternary converter circuit 40a shown in FIG. 8 is the same as the binary-to-ternary converter circuit 40a shown in FIG. 2. Each of the sense amplifiers 104 (SA0 and SA1) shown in FIG. 8 is the same as the sense amplifier shown in FIG. 3. An output signal V0 of the sense amplifier 104 (SA0) and an output signal V1 of the sense amplifier 104 (SA1) are each applied to a different one of the two input terminal of the AND gate 108. When the output signals V0 and V1 are applied to the AND gate 108, the AND gate 108 generates a defect signal Vdefect as an output signal. A voltage Vsw is applied to a noninverting input terminal of the sense amplifier 104 (SA0) and an inverting input terminal of the sense amplifier 104 (SA1) (It is possible that a voltage Vsw is applied to an inverting input terminal of the sense amplifier 104 (SA0) and a noninverting input terminal of the sense amplifier 104 (SA1).). A first reference voltage Vref1 is applied to the noninverting input terminal of the sense amplifier 104 (SA0). A second reference voltage Vref2 is applied to the inverting input terminal of the sense amplifier 104 (SA1). As shown in FIG. 9, when the voltages Vref1 and Vref2 are defined as VDD-R×1.5 I [A] and VDD-R×0.5 I [A], respectively, the multiple-valued defect self-detection circuit 40d implements an XOR function.

In another exemplary embodiment, it is possible that a voltage Vsw is applied to an inverting input terminal of the sense amplifier 104 (SA0) and a noninverting input terminal of the sense amplifier 104 (SA1).

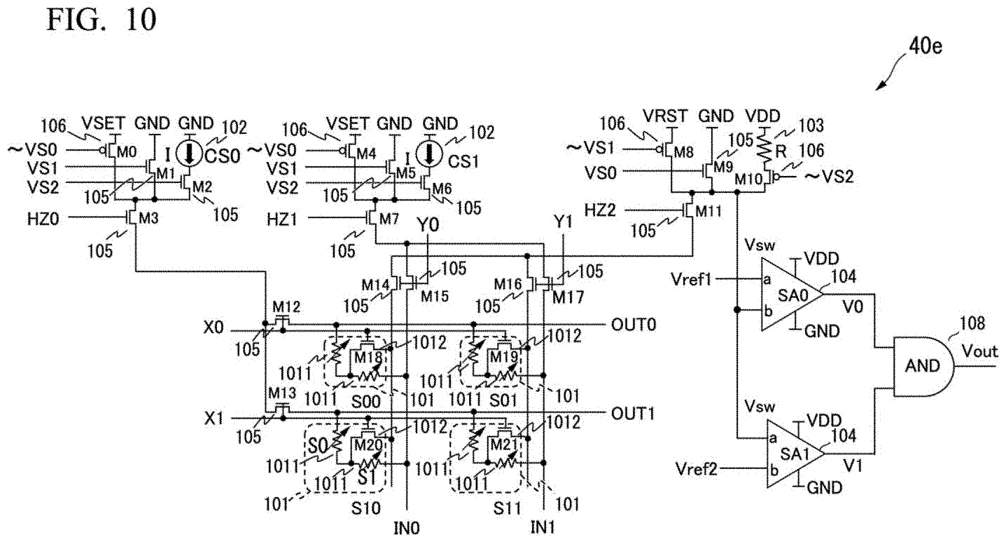

FIG. 10 shows a crossbar circuit 40e using the multiple-valued defect self-detection circuit 40d. The structure of the crossbar circuit 40e is almost the same as the crossbar circuit 40c shown in FIG. 5 except for using the sense amplifiers 104 (SA0 and SA1) and the AND gate 108 shown in FIG. 8 instead of the sense amplifier 104 (SA) shown in FIG. 5.

The multiple-valued circuits of the above exemplary embodiments may be used in, for example, mobile phone, IoT (Internet of Things) devices, and so on. A high-performance FPGA 1 using the CNVRSs 101 can be realized by the multiple-valued circuits described above.

It is apparent that the present invention is not limited to the above exemplary embodiments and examples, but may be modified and changed without departing from the scope and sprit of the invention.

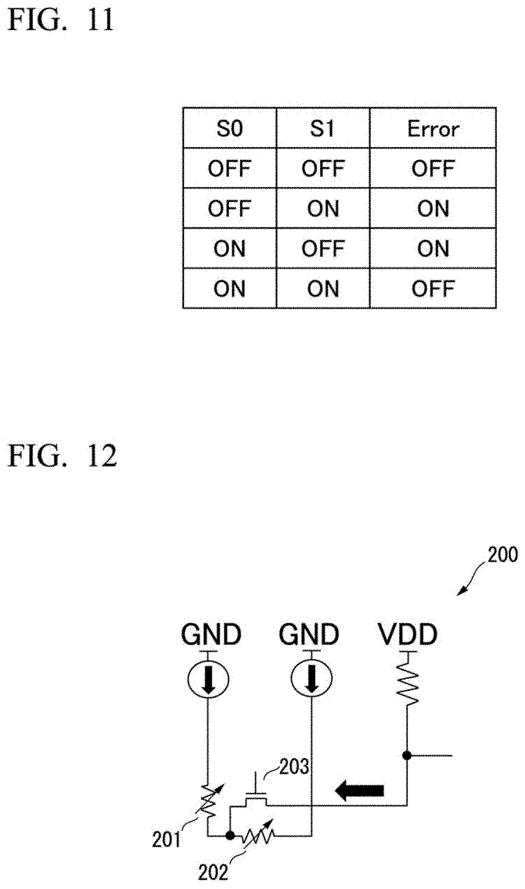

FIG. 11 shows a defect detection code introduced in [PTL 3]. In the normal situation, the ON/OFF state of S0 and S1 are the same with each other, there is no defect. Otherwise, if the ON/OFF state of S0 and S1 are different from each other, defect occurs. Therefore, the relationship of defect information and state information of S0 and S1 is an exclusive or (XOR) function.

### Structure of the Binary-to-Ternary Converter Circuit in Each Exemplary Embodiment

FIG. 12 shows a structure of the binary-to-ternary converter circuit in each exemplary embodiment. The binary-to-ternary converter circuit 200 comprises a first resistive switch 201, a second resistive switch 202 and a selection transistor 203. A first terminal of the first resistive switch 201 is connected to a first terminal of the second resistive 202 switch and a first terminal of the selection transistor 203. A second terminal of the first resistive switch 201 is connected to a first terminal of a first current source having a second terminal connected to a ground voltage line. A second terminal of the second resistive switch 202 is connected to a first terminal of a second current source having a second terminal connected to the ground voltage line. A second terminal of the selection transistor 203 is connected to a first terminal of a resistor having a second terminal connected to a power voltage line.

### <Configuration of Computer>

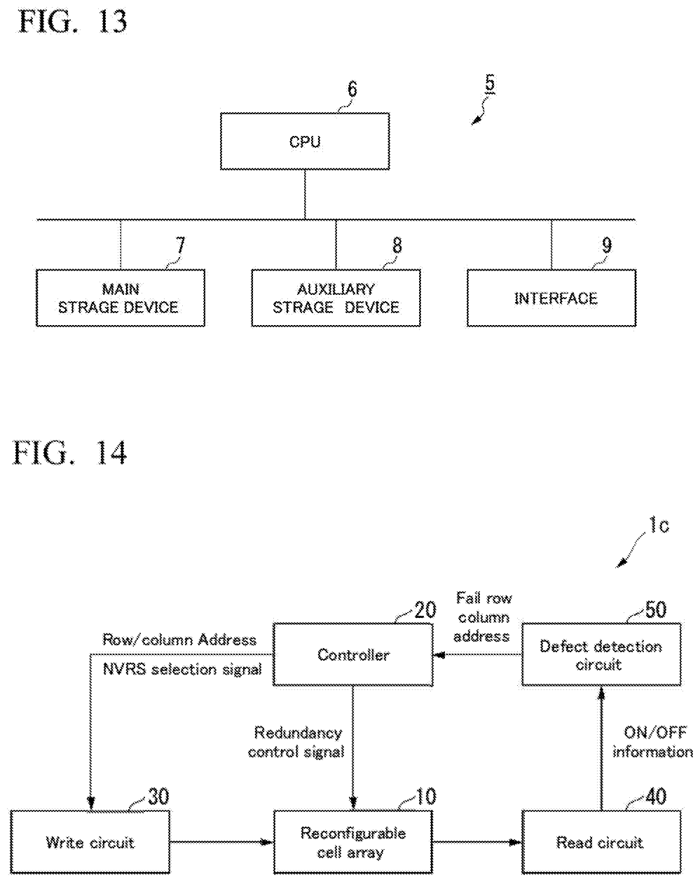

FIG. 13 is a schematic block diagram showing a configuration of a computer 5 according to at least one of the above-mentioned embodiments.

The computer 5 includes a central processing unit (CPU) 6, a main storage device 7, an auxiliary storage device 8, and an interface 9.

The controller 20 and other devices are mounted on the computer 5. The operations of the above-mentioned processing units are stored in the form of a program in the auxiliary storage device 8. The CPU 6 reads the program from the auxiliary storage device 8, loads the program into the main storage device 7, and performs the above-mentioned processes in accordance with the program.

In at least one of the above-mentioned embodiments, the auxiliary storage device 8 is an example of non-transitory media. As other example, a magnetic disk, a magneto-optical disk, a compact disc read-only memory (CD-ROM), a digital versatile disc (DVD)-ROM, and a semiconductor memory can be used as non-transitory media, and the interface 9 is connected to the non-transitory media. When the program is transmitted to the computer 5 via a communication line, the computer 5 receiving the program may load it into the main storage device 7 and perform the above-mentioned processes.

The program may serve to realize a part of the above-mentioned functions.

The program may be a so-called differential file (a differential program) which realizes the above-mentioned functions in combination with another program stored in the auxiliary storage device 8.

The whole or part of the example embodiments disclosed above can be described as, but not limited to, the following supplementary notes.

### Supplementary Note

### (Supplementary Note 1)

A reconfigurable circuit comprising:

a complementary resistive switch comprising a first resistive switch, a second resistive switch and a selection transistor, wherein

a first terminal of the first resistive switch is connected to a first terminal of the second resistive switch and connected to a first terminal of the selection transistor, and

a second terminal of the first resistive switch is a first terminal of the complementary resistive switch, a second terminal of the selection transistor is a second terminal of the complementary resistive switch, a second terminal of the second resistive switch is a third terminal of the complementary resistive switch;

a first current source having a first terminal connected to the first terminal of the complementary resistive switch and a second terminal connected to a ground voltage line;

a second current source having a first terminal connected to the third terminal of the complementary resistive switch and a second terminal connected to the ground voltage line; and

a resistor having a first terminal connected to the second terminal of the complementary resistive switch and a second terminal connected to a power voltage line.

### (Supplementary Note 2)

The reconfigurable circuit according to Supplementary note 1, wherein

a selection signal is applied to a third terminal of the selection transistor.

### (Supplementary Note 3)

The reconfigurable circuit according to Supplementary note 1 or 2, further comprising:

a sense amplifier having a first input terminal connected to the second terminal of the complementary resistive switch, and a second input terminal connected to a reference voltage line.

### (Supplementary Note 4)

The reconfigurable circuit according to Supplementary note 3, wherein

a voltage of the reference voltage line is set to VDD-R×1.5 I volts,

I denotes a current value of both the first and second current sources,

R denotes a resistance of the resistor, and

VDD denotes a voltage of the power voltage line.

### (Supplementary Note 5)

The reconfigurable circuit according to Supplementary note 1 or 2, further comprising:

a first sense amplifier having a first input terminal connected to a first reference voltage line and a second input terminal connected to the second terminal of the complementary resistive switch;

a second sense amplifier having a first input terminal connected to the second terminal of the complementary resistive switch, and a second input terminal connected to a second reference voltage line; and

an AND gate having a first input terminal connected to an output terminal of the first sense amplifier, and a second input terminal connected to the output terminal of the second sense amplifier.

### (Supplementary Note 6)

The reconfigurable circuit according to Supplementary note 5, wherein

the current value of both the first and second current sources is I amperes, the resistance of the resistor is R ohms, the power voltage is VDD volts, the first reference voltage is set as VDD-R×1.5 I volts and the second reference voltage is set as VDD-R×0.5 I volts.

### (Supplementary Note 7)

The reconfigurable circuit according to Supplementary note 1 or 2, further comprising:

more than two complementary resistive switches which each include a first resistive switch, a second resistive switch and a selection transistor arranged in a lattice manner, wherein

the first terminals of the complementary resistive switches at the same row are connected to each other and connected to a first terminal of a first transistor,

the second terminals of the complementary resistive switches at the same column are connected to each other and connected to a first terminal of a second transistor,

the third terminals of the complementary resistive switches at the same column are connected to each other and connected to a first terminal of a third transistor,

all second terminals of the first transistors are connected to each other and connected to a first terminal of a fourth transistor having a second terminal connected to the first terminal of the first current source via a fifth transistor,

all second terminals of the second transistors are connected to each other and connected to a first terminal of a sixth transistor having a second terminal connected to the first terminal of the resistor via a seventh transistor, and

all second terminals of the third transistors are connected to each other and connected to a first terminal of a eighth transistor having a second terminal connected to the first terminal of the second current source via an ninth transistor.

### (Supplementary Note 8)

The reconfigurable circuit according to Supplementary note 7, wherein

third terminals of the first transistor and the selection transistors at the same row are connected to each other and controlled by a row address signal, and

third terminals of the second transistor and third transistor at the same column are connected to each other and controlled by a column address signal.

### (Supplementary Note 9)

The reconfigurable circuit according to Supplementary note 7, wherein

a third terminal of the fourth transistor is controlled by a first high-Z selection signal,

a third terminal of the sixth transistor is controlled by a second high-Z selection signal, and

a third terminal of the eighth transistor is controlled by a third high-Z selection signal.

### (Supplementary Note 10)

The reconfigurable circuit according to Supplementary note 7, wherein

third terminals of the fifth and ninth transistors are controlled by a first voltage selection signal, a third terminal of the eighth transistor is controlled by the inverse of the first voltage selection signal.

### (Supplementary Note 11)

The reconfigurable circuit according to Supplementary note 7, wherein

the second terminal of the fourth transistor is connected to the ground voltage line via a tenth transistor and to a set voltage line via a eleventh transistor,

the second terminal of the sixth transistor is connected to the ground voltage line via a twelfth transistor and to a reset voltage line via a thirteenth transistor, and

the second terminal of the eighth transistor is connected to the ground voltage line via a fourteenth transistor and to a set voltage line via a fifteenth transistor.

### (Supplementary Note 12)

The reconfigurable circuit according to Supplementary note 11, wherein

the third terminals of the tenth and fourteenth transistors are controlled by a second voltage selection signal, a third terminal of the thirteenth transistor is controlled by the inverse of the second voltage selection signal,

the third terminal of the twelfth transistor is controlled by a third voltage selection signal, and

the third terminals of the eleventh and fifteenth transistors are controlled by the inverse of the third voltage selection signal.

### INDUSTRIAL APPLICABILITY

The present invention relates to a reconfigurable circuit using non-volatile complementary resistive switches.

### REFERENCE SIGNS LIST

1, 1a, 1b, 1c, 1d FPGA
5 Computer
6 CPU
7 Main storage device
8 Auxiliary storage device
9 Interface
10 reconfigurable cell array
20 controller
30 write circuit
40 read circuit
40a, 200 binary-to-ternary converter circuit
40b multiple-valued read circuit
40c, 40e crossbar circuit
40d multiple-valued defect self-detection circuit
50 defect detection circuit
60 routing multiplexer
70 logic block
100 cell
101 complementary NVRS
102 adjacent cell
103 resistor
104 sense amplifier
105 nMOS transistor
106 pMOS transistor
107 inverter
108 AND gate
201 first resistive switch
202 second resistive switch
203, 1012 selection transistor
601 input line, output line
701 look-up table
702 D-type flip-flop
703 selector
1011 NVRS

What is claimed is:

1. A reconfigurable circuit comprising:
a complementary resistive switch comprising a first resistive switch, a second resistive switch and a selection transistor, wherein
a first terminal of the first resistive switch is connected to a first terminal of the second resistive switch and connected to a first terminal of the selection transistor, and
a second terminal of the first resistive switch is a first terminal of the complementary resistive switch, a second terminal of the selection transistor is a second terminal of the complementary resistive switch, a second terminal of the second resistive switch is a third terminal of the complementary resistive switch;
a first current source having a first terminal connected to the first terminal of the complementary resistive switch and a second terminal connected to a ground voltage line;
a second current source having a first terminal connected to the third terminal of the complementary resistive switch and a second terminal connected to the ground voltage line; and
a resistor having a first terminal connected to the second terminal of the complementary resistive switch and a second terminal connected to a power voltage line.

2. The reconfigurable circuit according to claim 1, wherein
a selection signal is applied to a third terminal of the selection transistor.

3. The reconfigurable circuit according to claim 1, further comprising:
a sense amplifier having a first input terminal connected to the second terminal of the complementary resistive switch, and a second input terminal connected to a reference voltage line.

4. The reconfigurable circuit according to claim 3, wherein
a voltage of the reference voltage line is set to VDD-R×1.5 I volts,
I denotes a current value of both the first and second current sources,
R denotes a resistance of the resistor, and
VDD denotes a voltage of the power voltage line.

5. The reconfigurable circuit according to claim 1, further comprising:
a first sense amplifier having a first input terminal connected to a first reference voltage line and a second input terminal connected to the second terminal of the complementary resistive switch;
a second sense amplifier having a first input terminal connected to the second terminal of the complementary resistive switch, and a second input terminal connected to a second reference voltage line; and
an AND gate having a first input terminal connected to an output terminal of the first sense amplifier, and a second input terminal connected to the output terminal of the second sense amplifier.

6. The reconfigurable circuit according to claim 5, wherein
the current value of both the first and second current sources is I amperes, the resistance of the resistor is R ohms, the power voltage is VDD volts, the first reference voltage is set as VDD-R×1.5 I volts and the second reference voltage is set as VDD-R×0.5 I volts.

7. The reconfigurable circuit according to claim 1, further comprising:
more than two complementary resistive switches which each include a first resistive switch, a second resistive switch and a selection transistor arranged in a lattice manner, wherein
the first terminals of the complementary resistive switches at the same row are connected to each other and connected to a first terminal of a first transistor,
the second terminals of the complementary resistive switches at the same column are connected to each other and connected to a first terminal of a second transistor,
the third terminals of the complementary resistive switches at the same column are connected to each other and connected to a first terminal of a third transistor,
all second terminals of the first transistors are connected to each other and connected to a first terminal of a fourth transistor having a second terminal connected to the first terminal of the first current source via a fifth transistor,
all second terminals of the second transistors are connected to each other and connected to a first terminal of a sixth transistor having a second terminal connected to the first terminal of the resistor via a seventh transistor, and
all second terminals of the third transistors are connected to each other and connected to a first terminal of a eighth transistor having a second terminal connected to the first terminal of the second current source via an ninth transistor.

8. The reconfigurable circuit according to claim 7, wherein
third terminals of the first transistor and the selection transistors at the same row are connected to each other and controlled by a row address signal, and
third terminals of the second transistor and third transistor at the same column are connected to each other and controlled by a column address signal.

9. The reconfigurable circuit according to claim 7, wherein
a third terminal of the fourth transistor is controlled by a first high-Z selection signal,
a third terminal of the sixth transistor is controlled by a second high-Z selection signal, and
a third terminal of the eighth transistor is controlled by a third high-Z selection signal.

10. The reconfigurable circuit according to claim 7, wherein
third terminals of the fifth and ninth transistors are controlled by a first voltage selection signal, a third terminal of the eighth transistor is controlled by the inverse of the first voltage selection signal.

11. The reconfigurable circuit according to claim 7, wherein
the second terminal of the fourth transistor is connected to the ground voltage line via a tenth transistor and to a set voltage line via a eleventh transistor,
the second terminal of the sixth transistor is connected to the ground voltage line via a twelfth transistor and to a reset voltage line via a thirteenth transistor, and
the second terminal of the eighth transistor is connected to the ground voltage line via a fourteenth transistor and to a set voltage line via a fifteenth transistor.

12. The reconfigurable circuit according to claim 11, wherein
the third terminals of the tenth and fourteenth transistors are controlled by a second voltage selection signal, a third terminal of the thirteenth transistor is controlled by the inverse of the second voltage selection signal,
the third terminal of the twelfth transistor is controlled by a third voltage selection signal, and
the third terminals of the eleventh and fifteenth transistors are controlled by the inverse of the third voltage selection signal.
